(19) United States
(12) Patent Application Publication
(10) Pub. No.: US 2020/0395528 A1
(43) Pub. Date: Dec. 17, 2020

(54) Wiring Substrate, Method Of Manufacturing Wiring Substrate, Inkjet Head, MEMS Device, And Oscillator

(71) Applicant: Seiko Epson Corporation, Tokyo (JP)

(72) Inventors: Masahiro FUJII, Shiojiri (JP); Shinichi YOTSUYA, Chino (JP)

(21) Appl. No.: 16/899,624

(22) Filed: Jun. 12, 2020

(30) Foreign Application Priority Data
Jun. 13, 2019 (JP) 2019-110615

(51) Int. Cl. H01L 41/047; H01L 41/09; H01L 41/29; H05K 1/11; H05K 3/00; H05K 3/42; H05K 1/18; H03B 5/32; B41J 2/14; C25D 5/02; C23C 18/16

(52) U.S. Cl. CPC H01L 41/0475; H01L 41/0973; H01L 41/29; H05K 1/115; H05K 3/0017; H05K 3/42; B41J 2002/14491; H03B 5/32; B41J 2/14201; C25D 5/02; C23C 18/1603; H05K 2201/10083; H05K 1/181

(57) ABSTRACT

A wiring substrate includes a first substrate having a first surface and a second surface at an opposite side to the first surface, a first interconnection disposed on the first surface, a second interconnection disposed on the second surface, and a through interconnection electrically coupling the first interconnection and the second interconnection to each other, and penetrating the first substrate, wherein the through interconnection includes a first through interconnection coupled to the first interconnection, and a second through interconnection coupled to the second interconnection, and the first through interconnection and the second through interconnection partially overlap each other in a plan view from a thickness direction of the first substrate.

The present application is based on, and claims priority from JP Application Serial Number 2019-110615, filed Jun. 13, 2019, the disclosure of which is hereby incorporated by reference herein in its entirety.

### BACKGROUND

### 1. Technical Field

The present disclosure relates to a wiring substrate, a method of manufacturing a wiring substrate, an inkjet head, an MEMS device, and an oscillator.

### 2. Related Art

In JP-A-2017-201660 (Document 1), there is disclosed a method of manufacturing a through electrode, the method including a step of providing a through hole to a semiconductor substrate with metal-catalyzed etching, and a process of obtaining the through electrode by filling the through hole with a semiconductor material using a plating method.

The through electrode is a technology making three-dimensional mounting on the semiconductor substrate possible. By performing the three-dimensional mounting on the semiconductor substrate, it is possible to achieve an increase in density and reduction in size of an MEMS (Micro Electro Mechanical Systems) device using the semiconductor substrate in addition to an increase in density of the semiconductor device.

In Document 1, the etching process is executed on one surface of the semiconductor substrate when forming the through hole. Therefore, the through hole extends straight from the one surface to the other surface of the semiconductor substrate, as a result. In other words, there is formed a through hole extending straight without forming a step midway through the through hole. In that case, when forming the through electrode so as to fill the through hole, a friction between the through electrode and the through hole is difficult to occur. Therefore, it becomes easy for the through electrode to get out of the through hole, and there is a problem that the reliability of the through electrode degrades.

### SUMMARY

A wiring substrate according to an application example of the present disclosure includes a first substrate having a first surface and a second surface at an opposite side to the first surface, a first interconnection disposed on the first surface, a second interconnection disposed on the second surface, and a through interconnection electrically coupling the first interconnection and the second interconnection to each other, and penetrating the first substrate, wherein the through interconnection includes a first through interconnection coupled to the first interconnection, and a second through interconnection coupled to the second interconnection, and the first through interconnection and the second through interconnection partially overlap each other in a plan view from a thickness direction of the first substrate.

### BRIEF DESCRIPTION OF THE DRAWINGS

FIG. 1 is a cross-sectional view of a wiring substrate according to a first embodiment.

FIG. 2 is a partial enlarged view of the wiring substrate shown in FIG. 1.

FIG. 3 is a plan view showing a base end surface of a first through interconnection and a base end surface of a second through interconnection in a plan view from a thickness direction of a first substrate shown in FIG. 2.

FIG. 4 is a diagram showing a first modified example of FIG. 2.

FIG. 5 is a diagram showing a second modified example of FIG. 2.

FIG. 6 is a process chart for explaining a method of manufacturing the wiring substrate according to the first embodiment.

FIG. 7 is a diagram for explaining the method of manufacturing the wiring substrate shown in FIG. 6.

FIG. 8 is a diagram for explaining the method of manufacturing the wiring substrate shown in FIG. 6.

FIG. 9 is a diagram for explaining the method of manufacturing the wiring substrate shown in FIG. 6.

FIG. 10 is a diagram for explaining the method of manufacturing the wiring substrate shown in FIG. 6.

FIG. 11 is a diagram for explaining the method of manufacturing the wiring substrate shown in FIG. 6.

FIG. 12 is a diagram for explaining the method of manufacturing the wiring substrate shown in FIG. 6.

FIG. 13 is a diagram for explaining the method of manufacturing the wiring substrate shown in FIG. 6.

FIG. 14 is a diagram for explaining the method of manufacturing the wiring substrate shown in FIG. 6.

FIG. 15 is a diagram for explaining the method of manufacturing the wiring substrate shown in FIG. 6.

FIG. 16 is a cross-sectional view showing an inkjet head according to a second embodiment.

FIG. 17 is a cross-sectional view showing an ultrasonic actuator included in an MEMS device according to a third embodiment.

FIG. 18 is a cross-sectional view showing an oscillator according to a fourth embodiment.

### DESCRIPTION OF EXEMPLARY EMBODIMENTS

Hereinafter, some preferred embodiments of a wiring substrate, a method of manufacturing a wiring substrate, an inkjet head, an MEMS device, and an oscillator according to the present disclosure will be described in detail based on the accompanying drawings.

### 1. First Embodiment

Firstly, the wiring substrate and the method of manufacturing the wiring substrate according to a first embodiment will be described.

### 1.1 Wiring Substrate

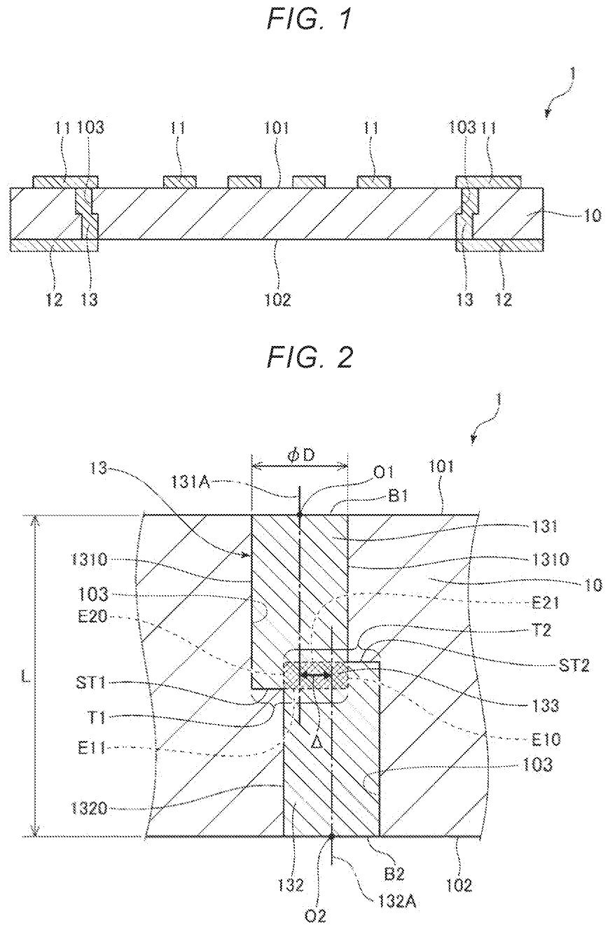

FIG. 1 is a cross-sectional view showing the wiring substrate according to the first embodiment.

The wiring substrate 1 has a first substrate 10, first interconnections 11, second interconnections 12, and through interconnections 13.

The substrate 10 is a semiconductor substrate. In other words, the first substrate 10 is a substrate at least partially formed of a semiconductor material. As the semiconductor material, there can be cited, for example, a IV-family element simple substance such as silicon or germanium, a compound of a III-family element and a V-family element such as gallium arsenide or gallium nitride, and a compound of a IV-family element and a IV-family element such as silicon carbide. It should be noted that the “family” in the present specification means the “family” in the short-form periodic table.

Further, in such a semiconductor material as described above, an impurity can be doped as needed. Further, in the first substrate 10, there can also be formed an element such as a transistor, a diode, a resister, or a capacitor as needed. It should be noted that the first substrate 10 is partially formed of an insulating material or an electrically-conductive material as needed.

The first substrate 10 is shaped like a flat plate, and has a first surface 101 and a second surface 102 having a relationship of two sides opposed to each other. In FIG. 1, an upper surface of the first substrate 10 corresponds to the first surface 101, and a lower surface corresponds to the second surface 102. The first substrate 10 is formed of, for example, a single-crystal substrate, a polycrystal substrate, or an amorphous substrate. Further, when the first substrate 10 is formed of a crystal substrate, any crystal plane can be exposed on the first surface 101 and the second surface 102.

On the first surface 101, there are disposed the first interconnections 11 which have electrical conductivity and are patterned to have arbitrary shapes. As the constituent material of the first interconnections 11, there can be cited, for example, a simple substance such as copper, gold, silver, nickel, or aluminum, or an alloy including these metals. It should be noted that it is possible for the first interconnection 11 to include a terminal to have electrical contact with another terminal.

On the second surface 102, there are disposed the second interconnections 12 which have electrical conductivity and are patterned to have arbitrary shapes. The constituent material of the second interconnections 12 is arbitrarily selected from the materials cited as the constituent material of the first interconnections 11. It should be noted that it is possible for the second interconnection 12 to include a terminal to have electrical contact with another terminal.

The first substrate 10 has at least one through hole 103 disposed so as to penetrate in the thickness direction to connect the first surface 101 and the second surface 102 to each other. The lateral cross-sectional shape of the through hole 103, namely the cross-sectional shape of the through hole 103 when being cut by a plane parallel to the first surface 101, is not particularly limited, but there can be cited, for example, a circular shape such as a circle, an ellipse, or an oval, a polygonal shape such as a quadrangular shape or a hexagonal shape, and other odd shapes.

Further, inside the through hole 103, there is disposed the through interconnection 13 having electrical conductivity. The through interconnection 13 is disposed so as to extend from the first surface 101 toward the second 102 to penetrate the first substrate 10. Then, the through interconnection 13 electrically couples the first interconnection 11 and the second interconnection 12 to each other. By using the through interconnection 13 in such a manner, since it becomes unnecessary to keep a space for laying interconnections for bypassing the first substrate 10, it is possible to achieve an increase in density and the reduction in size of the device using the wiring substrate 1.

As the constituent material of the through interconnections 13, there can be cited, for example, a simple substance such as copper, gold, silver, or nickel, or an alloy or a mixture including these metals.

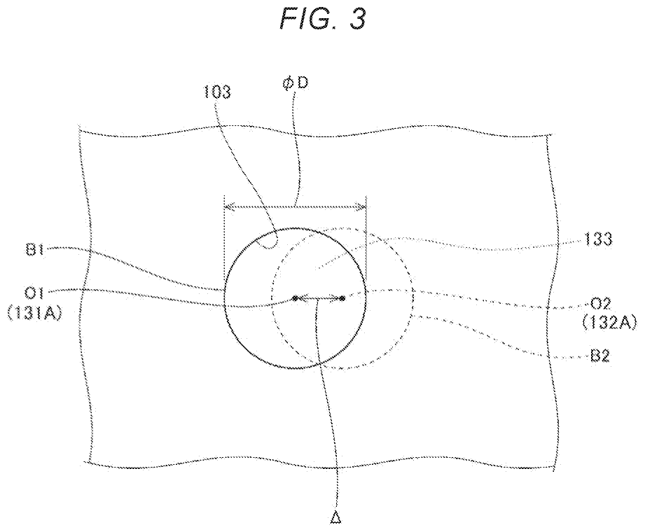

FIG. 2 is a partial enlarged view of the wiring substrate 1 shown in FIG. 1. It should be noted that in FIG. 2, the illustration of the first interconnections 11 and the second interconnections 12 is omitted. Further, FIG. 3 is a plan view showing a base end surface B1 of a first through interconnection 131 and a base end surface B2 of a second through interconnection 132 in a plan view from the thickness direction of the first substrate 10 shown in FIG. 2. It should be noted that an end surface at the first surface 101 side in the first through interconnection 131 is referred to as the “base end surface B1,” and an end surface at the opposite side to the base end surface B1 is referred to as a “tip surface T1.” It should be noted that the tip surface T1 means a virtual surface formed by translating the base end surface B1 to a position of a step ST1 along a normal line of the base end surface B1. Further, an end surface at the second surface 102 side in the second through interconnection 132 is referred to as the “base end surface B2,” and an end surface at the opposite side to the base end surface B2 is referred to as a “tip surface T2.” It should be noted that the tip surface T2 means a virtual surface formed by translating the base end surface B2 to a position of a step ST2 along a normal line of the base end surface B2.

As shown in FIG. 2, the through interconnection 13 has a shift midway through the extension of the through interconnection 13. Further, due to the shift, the through interconnection 13 is divided into two parts, namely a region located at an upper part in FIG. 2 and a region located at a lower part thereof bordered by the positions of the steps ST1, ST2 formed on the side surface of the through interconnection 13. Specifically, the through interconnection 13 shown in FIG. 2 is divided into the first through interconnection 131 as the region on the first surface 101 side, and the second through interconnection 132 as the region on the second surface 102 side. The first through interconnection 131 and the second through interconnection 132 each have a substantially columnar shape. Further, the first through interconnection 131 having a columnar shape and the second through interconnection 132 similarly having a columnar shape partially overlap each other while being shifted along the first surface 101 or the second surface 102. As a result of such an arrangement, on the side surface of the through interconnection 13, there is formed the step ST1 due to the first through interconnection 131, and at the same time, there is formed the step ST2 due to the second through interconnection 132. Further, it is conceivable that the first through interconnection 131 and the second through interconnection 132 each have an overlapping part 133 in common. The overlapping part 133 means a region represented by an area surrounded by an extended line E10 of a side surface 1310 of the first through interconnection 131, an extended line E11 of the step ST1, an extended line E20 of a side surface 1320 of the second through interconnection 132, and an extended line E21 of the step ST2 in FIG. 2.

When viewing the first through interconnection 131 and the second through interconnection 132 arranged as described above from the thickness direction of the first substrate 10 in a planar manner, specifically, the lateral cross-sectional surface of the first through interconnection 131 in the first surface 101, namely the base end surface B1, is viewed in a planar manner, and at the same time, the lateral cross-sectional surface of the second through interconnection 132 in the second surface 102, namely the base end surface B2, is viewed in a see-through manner. In this case, an axis 131A of the first through interconnection 131 and an axis 132A of the second through interconnection 132 are shifted from each other along the first surface 101 as shown in FIG. 2. It should be noted that the axis 131A denotes a normal line extending from the center O1 of the base end surface B1 of the first through interconnection 131. Similarly, the axis 132A denotes a normal line extending from the center O2 of the base end surface B2 of the second through interconnection 132.

Further, the center O1 of the base end surface B1 denotes the center of a circle (an inscribed circle) inscribed on the base end surface B1, and the center O2 of the base end surface B2 denotes the center of a circle inscribed on the base end surface B2. It should be noted that in the example shown in FIG. 3, the base end surface B1 forms a circular shape, and therefore coincides with the inscribed circle thereof. Similarly, the base end surface B2 also forms a circular shape, and therefore coincides with the inscribed circle thereof.

Further, as shown in FIG. 1, the first through interconnection 131 and the second through interconnection 132 each include the overlapping part 133 located in a central area of the thickness of the first substrate 10 as described above. Therefore, the first through interconnection 131 and the second through interconnection 132 have contact with each other, and at the same time, are electrically coupled to each other. The overlapping part 133 corresponds to a part where the base end part B1 and the base end part B2 overlap each other in FIG. 3.

Further, since the axis 131A and the axis 132A are shifted from each other, the through interconnection 13 becomes difficult to get out of the through hole 103 even when a force of pulling the through interconnection 13 out of the through hole 103 acts on the through interconnection 13. In other words, even when a pulling force is applied to the through interconnection 13, a strong frictional force due to the engagement between the steps ST1, ST2 is apt to occur between the through interconnection 13 and the through hole 103. Therefore, the through interconnection 13 becomes difficult to get out of the through hole 103. Thus, it is possible to prevent a problem such as breakage of the through interconnection 13 or an increase in electric resistance from occurring, and thus, it is possible to further increase the reliability of the wiring substrate 1. Further, it is possible to obtain an advantage that it is easy to reduce the diameter of the through interconnection 13 without degrading the reliability using these advantages. Thus, it becomes easy to achieve an increase in density and the reduction in size of the wiring substrate 1 without degrading the reliability of the wiring substrate 1.

It should be noted that in FIG. 2, the vertical cross-sectional shape when cutting the first through interconnection 131 with a plane perpendicular to the first surface 101 and the vertical cross-sectional shape when cutting the second through interconnection 132 with a plane perpendicular to the second surface 102 each have a rectangular shape. The corner part of these vertical cross-sectional shapes can be a right angle shown in FIG. 2, can be chamfered, or can be rounded.

In such a manner as described above, the wiring substrate 1 according to the present embodiment has the first substrate 10 having the first surface 101 and the second surface 102 at the opposite side to the first surface 101, the first interconnections 11 disposed on the first surface 101, the second interconnections 12 disposed on the second surface 102, and the through interconnections 13 electrically coupling the first interconnections 11 and the second interconnections 12 to each other to penetrate the first substrate 10. Further, the through interconnections 13 each include the first interconnection 131 coupled to the first interconnection 11 and the second through interconnection 132 coupled to the second interconnection 12. Further, in the plan view from the thickness direction of the first substrate 10, the first through interconnection 131 and the second through interconnection 132 partially overlap each other.

According to such a wiring substrate 1, since the first through interconnection 131 and the second through interconnection 132 are in the state of being shifted from each other, the through interconnection 13 is made easy to be caught on an inner surface of the through hole 103. Therefore, the through interconnection 13 becomes difficult to get out of the through hole 103, and the problem such as the breakage of the through interconnection 13 or the increase in the electrical resistance is prevented from occurring. Therefore, it is possible to further enhance the reliability of the wiring substrate 1.

Here, the axis 131A of the first through interconnection 131 and the axis 132A of the second through interconnection 132 shown in FIG. 2 and FIG. 3 are shifted from each other as described above. The shift amount Δ in this case can be defined as a distance between the axis 131A extending from the center O1 of the inscribed circle inscribed on the base end surface O1 of the first through interconnection 131, and the axis 132A extending from the center O2 of the inscribed circle inscribed on the base end surface B2 of the second through interconnection 132. In this case, it is preferable for the shift amount A to fulfill the following.

Δ≤(½)φD

Here, the symbol φD denotes smaller one of the diameter of the inscribed circle of the base end surface B1 and the diameter of the inscribed circle of the base end surface B2. In FIG. 3, it is assumed that the inscribed circle of the base end surface B1 is smaller as an example. Since such a relationship is fulfilled between the shift amount Δ and the diameter φD, it is possible to form an appropriate step in the inner surface of the through hole 103 while achieving the electrical coupling between the first through interconnection 131 and the second through interconnection 132. Thus, the through interconnection 13 becomes particularly difficult to get out of the through hole 103 while preventing the electrical resistance of the through interconnection 13 from increasing, and it is possible to enhance the reliability.

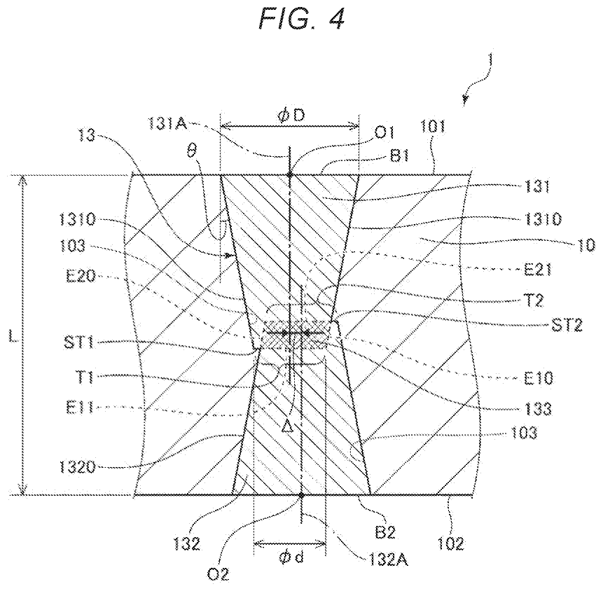

Incidentally, FIG. 4 is a diagram showing a first modified example of FIG. 2. It should be noted that in FIG. 4, it is also assumed that the diameter of the inscribed circle of the base end surface B1 is smaller than the diameter of the inscribed circle of the base end surface B2 as an example.

The first through interconnection 131 and the second through interconnection 132 shown in FIG. 2 described above each have a substantially columnar shape. In contrast, when the first through interconnection 131 shown in FIG. 4 is cut with a plane perpendicular to the first surface 101, the cross-sectional surface has a taper shape. Similarly, when the second through interconnection 132 shown in FIG. 4 is cut with a plane perpendicular to the second surface 102, the cross-sectional surface has a taper shape. In other words, the first through interconnection 131 and the second through interconnection 132 shown in FIG. 4 are each shaped like a substantially circular truncated cone. It should be noted that in the present specification, the “taper shape” means a cross-sectional shape of a circular truncated cone when being cut with a plane including the axial line.

Here, the diameter of a circle inscribed on the tip surface T1 of the first through interconnection 131 is denoted by φd. Further, the thickness of the first substrate 10 is denoted by L. In this case, the diameter φD of the inscribed circle of the base end surface B1, the diameter φd of the inscribed circle of the tip surface T1, and the thickness L fulfill the following relationship.

φd=φD−Ltanθ

It should be noted that the angle θ is an angle formed by a plane perpendicular to the first surface 101 and the side surface 1310 of the first through interconnection 131.

Taking this relationship into consideration, when the first through interconnection 131 and the second through interconnection 132 are each shaped like a substantially circular truncated cone, it is preferable for the shift amount Δ described above to further fulfill the following.

Δ≤φD−Ltanθ

Thus, even when the first through interconnection 131 and the second interconnection 132 are each shaped like a substantially circular truncated cone, it is possible to form an appropriate step on the inner surface of the through hole 103 while achieving the electrical coupling between the first through interconnection 131 and the second through interconnection 132. As a result, the advantage described above can more surely be obtained.

It should be noted that the angle θ can arbitrarily be adjusted in accordance with the constituent material and a method of forming the through hole 103 described later. For example, when providing the through hole 103 with an MACE (Metal Assisted Chemical Etching) method described later to the first substrate 10 as a P-type silicon substrate, there is a high probability that the angle 6 becomes not smaller than 5° and not larger than 11°, and there is a high probability that the angle θ becomes 8° on average. Taking the above into consideration, the angle θ is preferably not larger than 20°, more preferably not smaller than 1° and not larger than 15°, and further more preferably not smaller than 5° and not larger than 11°.

Further, the diameter φD is preferably not smaller than 10 μm and not larger than 200 μm as an example, and more preferably not smaller than 30 μm and not larger than 100 μm. Thus, it is possible to obtain the through interconnection 13 relatively small in electrical resistance on the one hand, and easy to achieve an increase in density on the other hand.

Further, the maximum value Amax of the shift amount A is different by the diameter φD and so on, and therefore cannot flatly be decided, but is preferably not smaller than 2 μm and not larger than 30 μm as an example, and more preferably not smaller than 3 μm and not larger than 25 μm.

Further, the ratio of the maximum value Δmax to the diameter φD is preferably not lower than 0.03 and not higher than 0.70, more preferably not lower than 0.05 and not higher than 0.50, and further more preferably not lower than 0.20 and not higher than 0.45. Thus, the through interconnection 13 becomes particularly difficult to get out of the through hole 103 while preventing the electrical resistance of the through interconnection 13 from increasing. As a result, it is possible to particularly enhance the reliability of the wiring substrate 1.

Further, the thickness L of the first substrate is not particularly limited, but is preferably not smaller than 200 μm and not larger than 1000 μm, and more preferably not smaller than 300 μm and not larger than 800 μm.

Further, since the first through interconnection 131 shown in FIG. 4 is shaped like the substantially circular truncated cone as described above, the cross-sectional area in the first surface 101 of the first through interconnection 131, namely the area of the base end surface B1 of the first through interconnection 131, is larger than the cross-sectional area of the first through interconnection 131 at a position coming closer to the second surface 102 from the first surface 101, namely the area of the tip surface T1 of the first through interconnection 131.

Thus, when the first through interconnection 131 is coupled to the first interconnection 11 on the base end surface B1, it is easy to prevent the resistance due to the connection from increasing. Therefore, it is easy to realize the wiring substrate 1 high in reliability. Further, when forming the first through interconnection 131 using, for example, a plating method, since it is easy to fill the through hole 103 with the plating solution, it is possible to deposit the electrically-conductive material so as to fill the through hole 103. As a result, there is also an advantage that it is easy to form the first though interconnection 131 high in filling rate and good in electrical conductivity.

Further, the stress generated due to the material constituting the first through interconnection 131 recrystallized and thus expanded, and the thermal stress generated due to the difference in thermal linear expansion coefficient can be converted into a force in the extending direction of the first through interconnection 131 due to the shape operation of the substantially circular truncated conic shape. As a result, it is possible to prevent the breakage of the first substrate 10 starting at the first through interconnection 131 generated due to the stress described above.

Meanwhile, since the second through interconnection 132 shown in FIG. 4 is also shaped like the substantially circular truncated cone as described above, the cross-sectional area in the second surface 102 of the second through interconnection 132, namely the area of the base end surface B2 of the second through interconnection 132, is larger than the cross-sectional area of the second through interconnection 132 at a position coming closer to the first surface 101 from the second surface 102, namely the area of the tip surface T2 of the second through interconnection 132.

Thus, when the second through interconnection 132 is coupled to the second interconnection 12 on the base end surface B2, it is easy to prevent the resistance due to the connection from increasing. Therefore, it is easy to realize the wiring substrate 1 high in reliability. Further, when forming the second through interconnection 132 using, for example, a plating method, since it is easy to fill the through hole 103 with the plating solution, it is possible to deposit the electrically-conductive material so as to fill the through hole 103. As a result, there is also an advantage that it is easy to form the second through interconnection 132 high in filling rate and good in electrical conductivity.

Further, the stress generated due to the material constituting the second through interconnection 132 recrystallized and thus expanded, and the thermal stress generated due to the difference in thermal linear expansion coefficient can be converted into a force in the extending direction of the second through interconnection 132 due to the shape operation of the substantially circular truncated conic shape. As a result, it is possible to prevent the breakage of the first substrate 10 starting at the second through interconnection 132 generated due to the stress described above.

It should be noted that each of the first through interconnection 131 and the second through interconnection 132 shown in FIG. 2 and FIG. 4 is preferably disposed so as to fill the inside of the through hole 103, but is not required to completely fill the inside. For example, it is also possible for the first through interconnection 131 and the second through interconnection 132 to be disposed along the inner wall of the through hole 103 while leaving a void in a central part. Further, another material can also be disposed in the void.

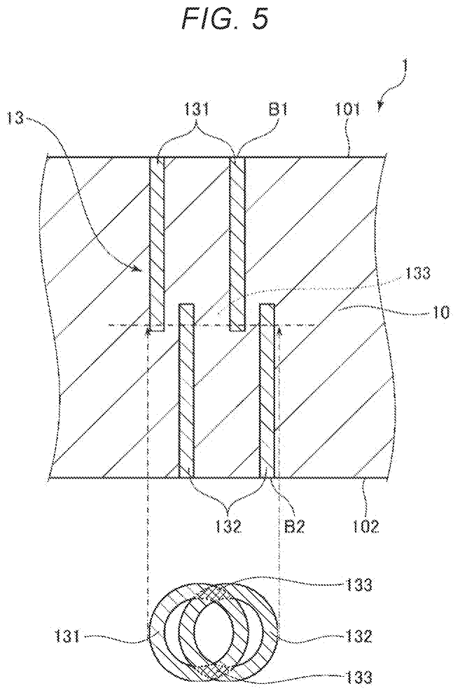

Further, FIG. 5 is a diagram showing a second modified example of FIG. 2.

The first through interconnection 131 and the second through interconnection 132 shown in FIG. 2 described above each have a substantially columnar shape. In contrast, the first through interconnection 131 shown in FIG. 5 has a cylindrical shape.

In this case, in the plan view from the thickness direction of the first substrate 10, the cross-sectional shape on the first surface 101 of the first through interconnection 131, namely the shape of the base end surface B1 of the first through interconnection 131, and the cross-sectional shape on the second surface 102 of the second through interconnection 132, namely the shape of the base end surface B2 of the second through interconnection 132, each have a ring-like shape.

According to such a shape, there is obtained a structure filled with the constituent material of the first substrate 10 along the central axis of the first through interconnection 131. Such a structure is a structure difficult to generate the stress compared to the first modified example. Therefore, it is possible to prevent the breakage of the first substrate 10 starting at the first through interconnection 131 generated due to the stress.

Similarly, the second through interconnection 132 shown in FIG. 5 also has a cylindrical shape. Therefore, it is possible to prevent the breakage of the first substrate 10 starting at the second through interconnection 132 generated due to the stress.

Further, the first through interconnection 131 and the second through interconnection 132 shown in FIG. 5 have contact with each other on the back side and the front side of the sheet of FIG. 5. In other words, the first through interconnection 131 and the second through interconnection 132 each having a cylindrical shape have contact with each other to form overlapping parts 133 shown in FIG. 5. The first through interconnection 131 and the second through interconnection 132 are electrically coupled to each other via the overlapping parts 133.

It should be noted that in FIG. 5, there is additionally described a cross-sectional view showing only the first through interconnection 131 and the second through interconnection 132 in the vicinity of the overlapping parts 133.

Further, in order to obtain the advantage described above, namely the advantage that it is difficult to generate the stress derived from the cylindrical shape, it is sufficient to provide the cylindrical shape to at least one of the first through interconnection 131 and the second through interconnection 132. Therefore, it is sufficient for at least one of the shape of the base end surface B1 and the shape of the base end surface B2 to have a ring-like shape, and it is possible for the other thereof to have another shape than the ring-like shape. It should be noted that the ring-like shape can be a circular ring, or can also be a shape having a polygonal shape in at least one of the outer edge and the inner edge.

Further, the first through interconnection 131 and the second through interconnection 132 each have a shape obtained by combining the shape shown in FIG. 4 and the shape shown in FIG. 5 with each other. In other words, the first through interconnection 131 and the second through interconnection 132 can each have the cylindrical shape, and at the same time, have a taper shape. Thus, it is possible to enhance the advantage that it is difficult for the first through interconnection 131 and the second through interconnection 132 to get out of the through hole 103 compared to what is shown in FIG. 5.

Although the wiring substrate 1 is described hereinabove, the shapes of the interconnection shown in the drawings are illustrative only. For example, the steps ST1, ST2 shown in the drawings are not required to be such distinct steps as illustrated, but can also have an obtuse corner part.

### 1.2 Method of Manufacturing Wiring Substrate

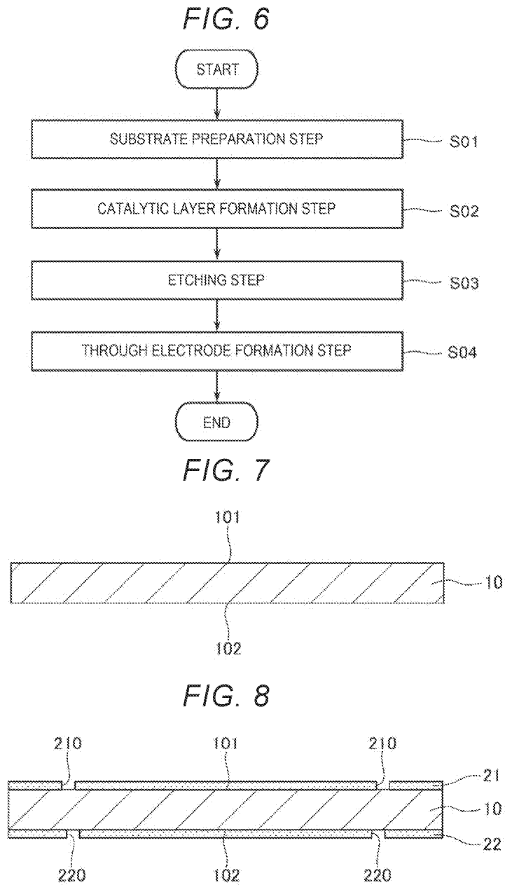

FIG. 6 is a process chart for explaining a method of manufacturing the wiring substrate according to the first embodiment. FIG. 7 through FIG. 15 are each a diagram for explaining the method of manufacturing the wiring substrate shown in FIG. 6.

The method of manufacturing the wiring substrate shown in FIG. 6 has a substrate preparation step S01, a catalytic layer formation step S02, an etching step S03, and a through interconnection formation step S04. Hereinafter, each of the steps will sequentially be described.

### 1.2.1 Substrate Preparation Step S01

Firstly, as shown in FIG. 7, the first substrate 10 is prepared. The first substrate 10 can also be, for example, a semiconductor wafer to be finally discretized into a plurality of the wiring substrates 1.

Further, it is also possible to perform an arbitrary pretreatment on the first substrate 10.

### 1.2.2 Catalytic Layer Formation Step S02

Then, a first mask layer 21 is formed on the first surface 101 of the first substrate 10. As shown in FIG. 8, the first mask layer 21 has opening parts 210 at areas where the first through interconnections 131 are going to be formed. Similarly, a second mask layer 22 is formed on the second surface 102 of the first substrate 10. As shown in FIG. 8, the second mask layer 22 has opening parts 220 at areas where the second through interconnections 132 are going to be formed. It should be noted that in FIG. 8, the positions of the opening part 210 and the opening part 220 are set so as to partially overlap each other in the plan view from the thickness direction of the first substrate 10. In other words, the opening part 210 and the opening part 220 are shifted from each other in the lateral position in FIG. 8. It should be noted that in the present manufacturing method, it is not essential to shift the position of the opening part 210 and the position of the opening part 220 from each other in the plan view. For example, it is also possible to make the inner diameter of the opening part 210 and the inner diameter of the opening part 220 different from each other although the positions are not shifted from each other. Even in this case, it is possible to finally form the through hole 103 having the step in the inner wall surface. Therefore, it becomes possible to form the through interconnection exerting substantially the same advantage as the advantage exerted by the through interconnection 13 described above. It should be noted that it is also possible to make the shape of the opening part 210 and the shape of the opening part 220 different from each other besides the inner diameters.

The constituent material of the first mask layer 21 and the second mask layer 22 is not particularly limited as long as the constituent material is a variety of types of resist materials which do not deteriorate when forming a catalytic layer described later, but there can be cited, for example, a variety of types of organic materials such as polyimide, fluorine resin, silicone resin, acrylic resin, and novolak resin, and a variety of inorganic materials such as silicon oxide and silicon nitride.

Further, the first mask layer 21 and the second mask layer 22 are each formed to have a desired shape using a known patterning technology. Among these, in the patterning of the mask layers using the organic material, it is possible to use photolithography. Further, in the patterning of the mask layers using the inorganic material, it is possible to use a method of combining the formation of the mask using the photolithography and the removal of the material using etching with each other.

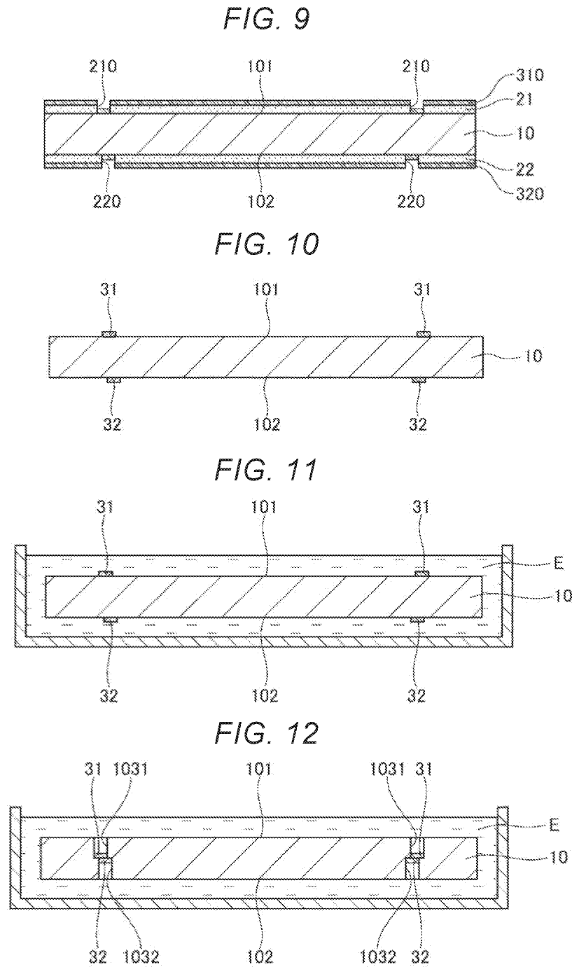

After forming the first mask layer 21 in such a manner, a catalytic material for forming a first catalytic layer 31 is deposited thereon. Thus, as shown in FIG. 9, there is obtained a catalytic material layer 310 covering the first mask layer 21 and the inside of each of the opening parts 210.

Similarly, a catalytic material for forming a second catalytic layer 32 is deposited from above the second mask layer 22. Thus, as shown in FIG. 9, there is obtained a catalytic material layer 320 covering the second mask layer 22 and the inside of each of the opening parts 220.

Here, the “catalyst” means the catalyst for a reaction between the first substrate 10 and the etchant in the etching step S03 described later. Due to the reaction with the etchant, an oxidation reaction occurs in the first substrate 10, and thus, it is possible to perform a work of removing the first substrate 10.

The catalytic material is a material including noble metal such as gold, silver, platinum, palladium, or rhodium. It should be noted that it is also possible to include two or more elements of noble metal.

The first catalytic layer 31 and the second catalytic layer 32 can each be deposited using a variety of vapor phase deposition methods such as a sputtering method and evaporation method, but can also be deposited using a variety of liquid phase deposition methods or a variety of plating methods.

Further, each of the first catalytic layer 31 and the second catalytic layer 32 preferably has a porous form. Thus, the first catalytic layer 31 and the second catalytic layer 32 make infiltration and replacement of the etchant easy in the etching step S03 described later. Therefore, it is possible to achieve an improvement in the etching rate and an improvement in the etching depth, and thus, the work high in aspect ratio can be performed in a shorter time.

It should be noted that as a method of forming the porous form, there can be cited a method of using a porous material, a method of achieving the porous form using patterning, and so on.

The thickness of the first catalytic layer 31 and the thickness of the second catalytic layer 32 are not particularly limited, but are preferably in a level not smaller than 5 nm and not larger than 100 nm, and more preferably in a level not smaller than 10 nm and not larger than 50 nm. Thus, when the first catalytic layer 31 and the second catalytic layer 32 each have such a porous form as described above, the infiltration and the replacement of the etchant are made easier in the etching step S03 described later. Therefore, it is possible to achieve an improvement in the etching rate and an improvement in the etching depth, and thus, the work high in aspect ratio can be performed in a shorter time.

Then, the first mask layer 21 and the second mask layer 22 are removed. Thus, a part located on the first mask layer 21 of the catalytic material layer 310 is removed together with the first mask layer 21 due to a so-called liftoff phenomenon. As a result, the catalytic material layer 310 deposited inside the opening part 210 remains alone to form the first catalytic layer 31 shown in FIG. 10. Similarly, a part located on the second mask layer 22 of the catalytic material layer 320 is removed together with the second mask layer 22 due to the so-called liftoff phenomenon. As a result, the catalytic material layer 320 deposited inside the opening part 220 remains alone to form the second catalytic layer 32.

### 1.2.3 Etching Step S03

Then, an etching process is performed on the first substrate 10 provided with the first catalytic layer 31 and the second catalytic layer 32. Specifically, as shown in FIG. 11, the first substrate 10 provided with the first catalytic layer 31 and the second catalytic layer 32 is made to have contact with the etchant E by being dipped or the like.

The etchant E is not particularly limited providing the etchant E is a liquid capable of dissolving to remove the first substrate 10 with the noble metal included in the first catalytic layer 31 and the second catalytic layer 32 as the catalyst, but a liquid including hydrofluoric acid and oxidizing agent is used as an example. As the oxidizing agent, there can be cited, for example, hydrogen peroxide and nitric acid.

In the etching process, the etchant E and the first surface 101 of the first substrate 10 react with each other with the noble metal included in the first catalytic layer 31 as the catalyst. Specifically, the oxidizing agent oxidizes the first surface 101, and then the hydrofluoric acid dissolves to remove the oxide. Thus, the first surface 101 is processed along the normal line, and the position gradually moves toward the second surface 102 as a result. Thus, the first surface 101 is dug down toward the second surface 102, and thus, first holes 1031 shown in FIG. 12 are formed.

Similarly, the etchant E and the second surface 102 of the first substrate 10 react with each other with the noble metal included in the second catalytic layer 32 as the catalyst. Thus, the second surface 102 is processed along the normal line, and the position gradually moves toward the first surface 101 as a result. Thus, the second surface 102 is dug down toward the first surface 101, and thus, second holes 1032 shown in FIG. 12 are formed. It should be noted that the proceeding direction of the etching in the first surface 101 may be changed due to the crystal direction and so on of the first substrate 10, and therefore, can also be a different direction from the direction perpendicular to the first surface 101, for example, a direction obtained by tilting the direction perpendicular to the first surface 101 as much as an arbitrary angle. Similarly, the proceeding direction of the etching in the second surface 102 can also be a different direction from the direction perpendicular to the second surface 102, for example, a direction obtained by tilting the direction perpendicular to the second surface 102 as much as an arbitrary angle.

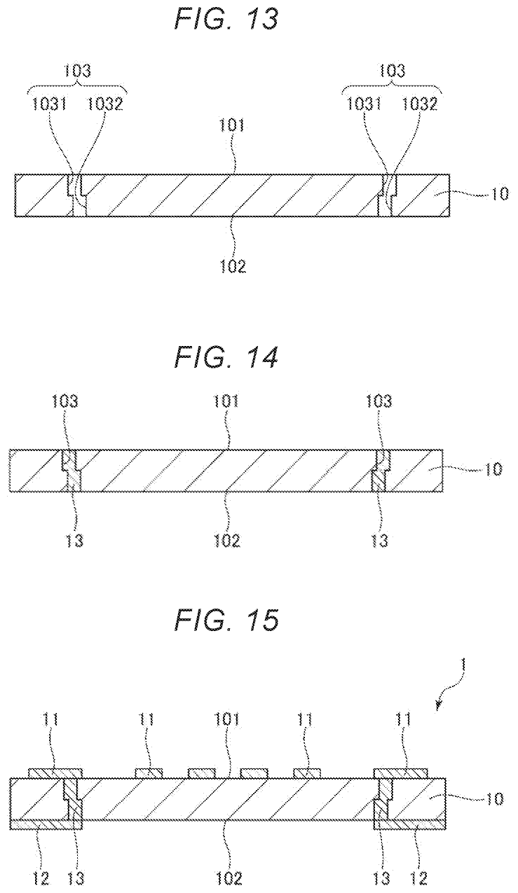

Then, when the first surface 101 thus dug down and the second surface 102 thus dug down have contact with each other, the first hole 1031 and the second hole 1032 are connected to each other. Thus, the through holes 103 shown in FIG. 13 are obtained.

The concentration of the hydrofluoric acid in the etchant E is not particularly limited, but is preferably not lower than 1.0 mol/L and not higher than 20 mol/L, and more preferably not lower than 5.0 mol/L and not higher than 10 mol/L. By setting the concentration of the hydrofluoric acid within the range described above, it is possible to suppress the side etching to increase the processing accuracy while sufficiently keeping the etching rate in the etching of the first holes 1031 and the second holes 1032.

Further, the concentration of the oxidizing agent in the etchant E is not particularly limited, but is preferably not lower than 0.2 mol/L and not higher than 8.0 mol/L, and more preferably not lower than 2.0 mol/L and not higher than 4.0 mol/L. By setting the concentration of the oxidizing agent within the range described above, it is possible to suppress the side etching to increase the processing accuracy while sufficiently keeping the etching rate in the etching of the first holes 1031 and the second holes 1032.

It should be noted that when the first catalytic layer 31 and the second catalytic layer 32 each have a ring-like shape, the replacement of the etchant E becomes easier compared to when the first catalytic layer 31 and the second catalytic layer 32 do not have a ring-like shape. Therefore, it is possible to efficiently form the through holes 103 particularly high in aspect ratio.

Further, in the catalytic layer formation step S02, namely the step of forming the first catalytic layer 31 and the second catalytic layer 32, it is possible to arrange that the first catalytic layer 31 and the second catalytic layer 32 are formed so that the first catalytic layer 31 and the second catalytic layer 32 partially overlap each other in the plan view from the thickness direction of the first substrate 10. Thus, in the present step, the first holes 1031 and the second holes 1032 are formed in accordance with the positions of the first catalytic layers 31 and the second catalytic layers 32. Therefore, it is possible to form the first hole 1031 and the second hole 1032 at the positions where the respective axes are shifted from each other. As a result, it becomes possible to form the first through interconnection 131 and the second through interconnection 132 arranged so as to partially overlap each other in the plan view as described above.

Subsequently, the first substrate 10 is made to have contact with a dissolving liquid for dissolving the noble metal. Thus, the first catalytic layer 31 and the second catalytic layer 32 are removed, and thus, the first substrate 10 provided with the through holes 103 shown in FIG. 13 is obtained.

It should be noted that although in the present step, it is also possible to arrange that when forming each of the first hole 1031 and the second hole 1032 using the etching process, the etching process is performed until the first hole 1031 and the second hole 1032 are connected to each other, it is also possible to stop the etching process before the first hole 1031 and the second hole 1032 are connected. In that case, it is sufficient to perform the work of connecting the first hole 1031 and the second hole 1032 to each other with subsequent post-processing. As an example of the post-processing, there can be cited, for example, laser processing.

Then, an insulating film not shown is formed on the surfaces of the first substrate 10, specifically the first surface 101, the second surface 102, and surfaces of the through holes 103. The insulating film is, for example, an organic film or an inorganic film. Specifically, when the first substrate 10 is a silicon substrate, there can be cited an inorganic film such as a thermally-oxidized film or a CVD (Chemical Vapor Deposition) film formed of silicon oxide as the insulating film. It should be noted that the thickness of the inorganic film is preferably not smaller than 800 nm and not larger than 1600 nm as an example. Incidentally, as the organic film, there can be cited, for example, a resin film.

### 1.2.4 Through Electrode Formation Step S04

Then, an electrically-conductive material is supplied inside the through holes 103. Thus, the through interconnections 13 shown in FIG. 14 are formed.

As a method of supplying the electrically-conductive material, there can be cited, for example, application of an electrically-conductive paste, a plating method, and an evaporation method. Among these, the plating method is preferably used from a viewpoint of production efficiency, electrical conductivity, and so on. The plating method can be an electrolytic plating method, or can also be an electroless plating method.

As the electrically-conductive material, there can be cited, for example, a simple substance such as copper, gold, silver, or nickel, or an alloy or a mixture including these metals.

Subsequently, the first interconnections 11 are formed on the first surface 101 of the first substrate 10. Similarly, the second interconnections 12 are formed on the second surface 102 of the first substrate 10. The first interconnections 11 and the second interconnections 12 can be formed by depositing the electrically-conductive material and then patterning the electrically-conductive material thus deposited.

In such a manner as described above, the wiring substrate 1 shown in FIG. 15 is obtained.

It should be noted that although not shown in the drawings, when a plurality of element areas is formed in the first substrate 10, there is provided a step of cutting to discretize the first substrate 10. Thus, it is possible to cut out the wiring substrates 1.

As described above, the method of manufacturing the wiring substrate 1 according to the present embodiment includes the substrate preparation step S01 of preparing the first substrate 10 having the first surface 101 and the second surface 102 at the opposite side to the first surface 101, the catalytic layer formation step SO2 of forming the first catalytic layer 31 including the noble metal on the first surface 101 and forming the second catalytic layer 32 including the noble metal on the second surface 102, the etching step S03 including a step of making the first substrate 10 provided with the first catalytic layer 31 and the second catalytic layer 32 have contact with the etchant E to perform the etching from the first surface 101 toward the second surface 102 to thereby form the first holes 1031, and at the same time perform the etching from the second surface 102 toward the first surface 101 to thereby form the second holes 1032, and thus connecting the first holes 1031 and the second holes 1032 to each other to obtain the through holes 103, and the through electrode formation step S04 of supplying the electrically-conductive material inside the through holes 103 to form the through interconnections 13.

According to such a manufacturing method, the through holes 103 are obtained by forming the first holes 1031 from the first surface 101 side while forming the second holes 1032 from the second surface 102 side. In other words, the through holes 103 are obtained by the etching of the first substrate 10 from the both surfaces. Therefore, it is possible to efficiently manufacture the wiring substrate 1.

Further, by using the wet etching process using the catalytic layers including the noble metal, it is possible to keep the high productivity while suppressing the capital investment compared to a sheet-by-sheet process such as a dry etching process.

Further, by forming the first catalytic layer 31 and the second catalytic layer 32 so as to be shifted from each other in such a manner as described above, it is possible to form the first hole 1031 and the second hole 1032 at the positions where the axes thereof are shifted from each other, and thus, it is possible to obtain the through hole 103 having the step on the inner surface thereof. By filling such a through hole 103 with the electrically-conductive material, the through interconnection 13 becomes easy to be caught on the inner surface of the through hole 103, and thus becomes difficult to get out of the through hole 103. Therefore, it is possible to manufacture the wiring substrate 1 higher in reliability.

### 2. Second Embodiment

Then, an inkjet head according to a second embodiment will be described.

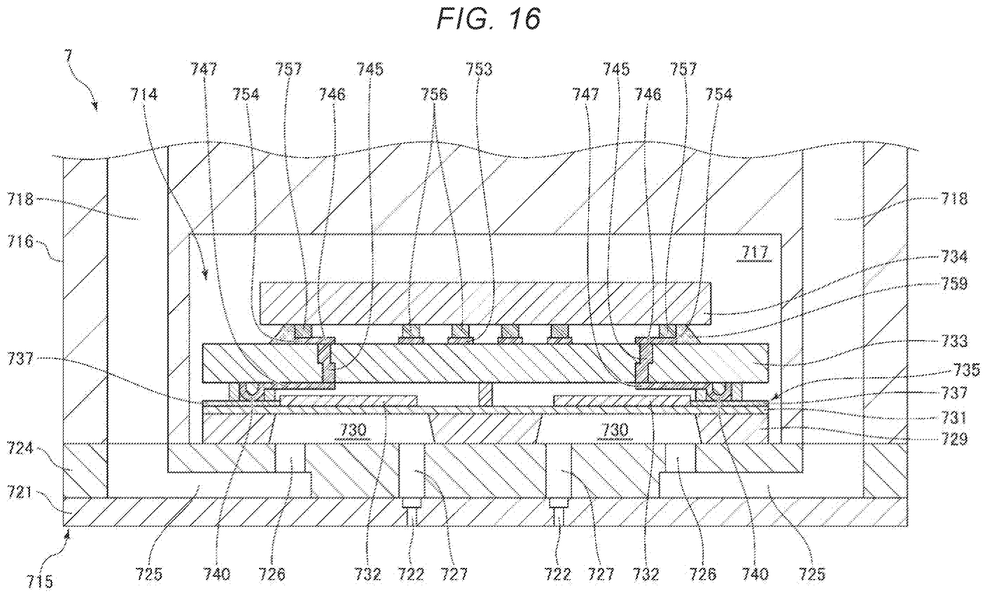

FIG. 16 is a cross-sectional view showing the inkjet head according to the second embodiment. It should be noted that the upper side of FIG. 16 is referred to as an “upper side,” and the lower side thereof is referred to as a “lower side” in the following descriptions for the sake of convenience of explanation.

The inkjet head 7 shown in FIG. 16 is provided with a piezoelectric device 714, a flow channel unit 715, and a head case 716. The piezoelectric device 714 and the flow channel unit 715 are attached to the head case 716 in a state of being stacked on one another.

The head case 716 is a box-like member, and is provided with liquid introduction channels 718 for supplying common liquid chambers 725 described later with ink, respectively, disposed inside. The liquid introduction channels 718 are each a space for retaining the ink together with the common liquid chamber 725, and in the present embodiment, there are two liquid introduction channels 718 so as to correspond to the columns of pressure chambers 730 arranged in two columns. Further, between the two liquid introduction channels 718, there is disposed a housing space 717 recessed from the lower surface side of the head case 716 to a midway position in the height direction of the head case 716 so as to form a rectangular solid shape. In the housing space 717, there is housed the piezoelectric device 714 stacked on a communication substrate 724 described later.

The flow channel unit 715 is bonded to a lower surface of the head case 716. The flow channel unit 715 has the communication substrate 724 and a nozzle plate 721. The communication substrate 724 has the common liquid chambers 725 respectively communicated with the liquid introduction channels 718 to retain the ink common to the pressure chambers 730, and individual communication channels 726 for individually supplying the ink from the liquid introduction channels 718 to the respective pressure chambers 730 via the common liquid chambers 725. The common liquid chambers 725 are arranged in the two columns so as to correspond to the columns of the pressure chambers 730 arranged in the two columns. The individual communication channels 726 are each communicated with an end part on one end in the longitudinal direction of the corresponding pressure chamber 730 located at a position where the common liquid chamber 725 and the pressure chamber 730 are connected to each other.

Further, at a position corresponding to an end part on the other end in the longitudinal direction of the pressure chamber 730 in the communication substrate 724, there is disposed a nozzle communication channel 727 penetrating in a plate thickness direction of the communication substrate 724. The plural nozzle communication channels 727 are disposed along a direction in which the nozzles 722 are arranged, and each communicate the pressure chamber 730 and the nozzle 722 with each other.

The nozzle plate 721 is bonded to a lower surface of the communication substrate 724. With the nozzle plate 721, an opening on the lower surface side of the space to be the common liquid chamber 725 is sealed. Further, the nozzle plate 721 is provided with a plurality of nozzles 722 disposed so as to be arranged in a straight line. In FIG. 16, the nozzles 722 are arranged in the two columns so as to correspond to the columns of the pressure chambers 730 arranged in the two columns.

A pressure chamber formation substrate 729, a vibrating plate 731, a piezoelectric element 732, a sealing plate 733, and a drive IC 734 are stacked on one another to be unitized, and are housed in the housing space 717.

The pressure chamber formation substrate 729 has a plurality of spaces to be used as the pressure chambers 730 along the direction in which the nozzles 722 are arranged. This space is zoned by the communication substrate 724 on the lower side, and is zoned by the vibrating plate 731 on the upper side to form the pressure chamber 730. Therefore, the pressure chamber 730 has a long axis in a direction perpendicular to the direction in which the nozzles 722 are arranged.

Further, on the lower side of the sealing plate 733, there is disposed a piezoelectric element substrate having the vibrating plate 731, and the piezoelectric elements 732 provided to the vibrating plate 731.

The vibrating plate 731 is a film-like member having elasticity, and is stacked on the upper surface of the pressure chamber formation substrate 729. A part corresponding to the pressure chamber 730 of the vibrating plate 731 functions as a displacement part displaced in a direction of getting away from or a direction of coming closer to the nozzle 722 due to a flexural deformation of the piezoelectric element 732. Due to this displacement, the capacity of the pressure chamber 730 changes.

The piezoelectric element 732 is a piezoelectric element in a so-called flexural mode. The piezoelectric element 732 is provided with, for example, a lower electrode layer, a piezoelectric layer, and an upper electrode layer stacked in sequence in an area corresponding to the pressure chamber 730 in the upper surface of the vibrating plate 731. Such a piezoelectric element 732 makes the flexural deformation in the direction of getting away from or the direction of coming closer to the nozzle 722 when generating a potential difference between the lower electrode layer and the upper electrode layer. Further, the piezoelectric elements 732 are arranged in two columns along the direction in which the nozzles 722 are arranged. Further, drive interconnections 737 are laid from the respective piezoelectric elements 732. The drive interconnections 737 are each an interconnection for supplying a drive signal to the piezoelectric element 732, and are each laid from the piezoelectric element 732 to an end part of the vibrating plate 731 so as to extend in a direction perpendicular to the direction in which the nozzles 722 are arranged.

The sealing plate 733 is a substrate shaped like a flat plate coupled to the vibrating plate 731 so as to form a space with the vibrating plate 731. On the upper surface of the sealing plate 733, there is disposed the drive IC 734 for outputting the drive signals for driving the piezoelectric elements 732. Further, on the lower surface of the sealing plate 733, there is disposed a plurality of bumps 740 for outputting the drive signals from the drive IC 734 toward the piezoelectric elements 732. The bump 740 is disposed at a position corresponding to the drive interconnection 737, and has contact with the drive interconnection 737 to thereby be electrically coupled.

Further, the sealing plate 733 is provided with power supply interconnections 753 to be supplied with the power supply voltages, connection terminals 754 to which signals from the drive IC 734 are input, upper surface side interconnections 746 disposed so as to extend from the connection terminals 754, through interconnections 745 penetrating the sealing plate 733, and lower surface side interconnections 747 coupled to the upper surface side interconnections 746 via the through interconnections 745.

Incidentally, the drive IC 734 is bonded on the sealing plate 733 via an adhesive 759 such as an anisotropically-conductive film. Further, the drive IC 734 is provided with power supply bump electrodes 756 and drive bump electrodes 757. Further, to the power supply interconnections 753, there are coupled the power supply bump electrodes 756, and to the connection terminals 754, there are coupled the drive bump electrodes 757.

In such an inkjet head 7 as described hereinabove, the ink from an inkjet cartridge not shown is introduced into the pressure chambers 730 via the liquid introduction channels 718, the common liquid chambers 725 and the individual communication channels 726. In this state, the drive signals from the drive IC 734 are supplied to the piezoelectric elements 732 via the respective interconnections and so on disposed on the sealing plate 733. Thus, the piezoelectric elements 732 are driven to generate pressure variations in the pressure chambers 730. The ink introduced into the pressure chambers 730 is ejected as ink droplets from the nozzles 722 via the nozzle communication channels 727 using the pressure variations.

In such an inkjet head 7, it is possible to apply the wiring substrate 1 described above to the structure provided with the sealing plate 733, and the electrodes, the interconnections, and so on provided to the sealing plate 733. In other words, the sealing plate 733 corresponds to the first substrate 10 described above, the upper surface side interconnections 746 correspond to the first interconnections 11 described above, the lower surface side interconnections 747 correspond to the second interconnections 12 described above, and the through interconnections 745 correspond to the through interconnections 13 described above.

Therefore, the inkjet head 7 according to the present embodiment is provided with a structure including the sealing plate 733 to which the wiring substrate 1 described above is applied, and the piezoelectric element substrate 735 having the vibrating plate 731 (a second substrate), and the piezoelectric elements 732 which are disposed on the vibrating plate 731, and electrically coupled to the lower surface side interconnections 747 (the second interconnections). Further, the wiring substrate 1 and the piezoelectric element substrate 735 are stacked on one another.

In such an inkjet head 7, since the failure such as broken line due to the missing of the through interconnections 745 is difficult to occur, it is possible to increase the reliability of the structure including the sealing plate 733. Further, due to such reliability, reduction in size and an increase in density of the sealing plate 733 become possible. Therefore, it is possible to realize the inkjet head 7 small in size and high in reliability.

### 3. Third Embodiment

Then, an MEMS device according to a third embodiment will be described.

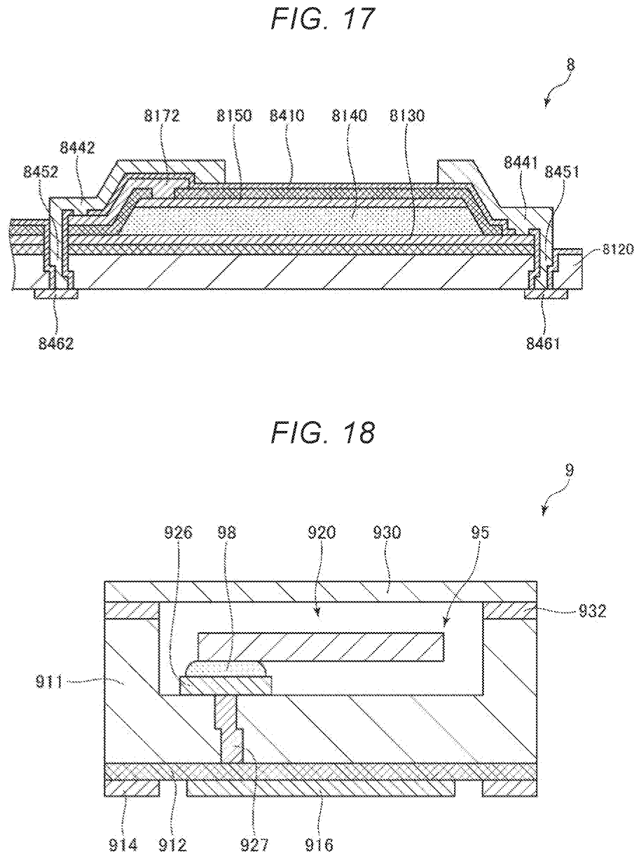

FIG. 17 is a cross-sectional view showing an ultrasonic actuator included in the MEMS device according to the third embodiment.

The ultrasonic actuator 8 shown in FIG. 17 has a stacked structure provided with a substrate 8120, a first electrode 8130 disposed on the substrate 8120, a piezoelectric body 8140 (an element) disposed on the first electrode 8130, a second electrode 8150 disposed on the piezoelectric body 8140, and a lead electrode 8172 coupled to the second electrode 8150. Further, on the entire surface of this stacked structure, there is disposed an insulating film 8410. Further, the ultrasonic actuator 8 has through electrically-conductive sections 8451, 8452 penetrating the substrate 8120, a first electrically-conductive layer 8441 coupled to the first electrode 8130, and a second electrically-conductive layer 8442 coupled to the second electrode 8150 and the lead electrode 8172. Further, the ultrasonic actuator 8 has electrode pads 8461, 8462 disposed at the lower end of the through electrically-conductive sections 8451, 8452.

Such an ultrasonic actuator 8 vibrates by energization, and drives a rotor or the like as a driven section not shown. Thus, the ultrasonic actuator 8 and the rotor constitute a piezoelectric drive device as an example of the MEMS device.

In such an ultrasonic actuator 8, it is possible to apply the wiring substrate 1 described above to the structure including the substrate 8120, and the electrically-conductive section, the electrodes, the interconnections, and so on provided to the substrate 8120. Thus, the wiring substrate 1 and the elements described above are electrically coupled to each other, and the wiring substrate 1 and the elements are stacked on one another.

Therefore, the ultrasonic actuator 8 included in the MEMS device according to the present embodiment is provided with the wiring substrate 1 described above and the elements. Further, the wiring substrate 1 and the elements are electrically coupled to each other, and the wiring substrate 1 and the elements are stacked on one another. Since the failure such as the broken line due to the missing of the through electrically-conductive sections 8451, 8452 penetrating the substrate 8120 is difficult to occur, such an ultrasonic actuator 8 becomes high in reliability. Further, due to such reliability, reduction in size and an increase in density of the ultrasonic actuator 8 become possible. Therefore, it is possible to realize the ultrasonic actuator 8 small in size and high in reliability, and the piezoelectric drive device (the MEMS device) provided with the ultrasonic actuator 8.

### 4. Fourth Embodiment

Then, an oscillator according to a fourth embodiment will be described.

FIG. 18 is a cross-sectional view showing the oscillator according to the fourth embodiment.

The oscillator 9 shown in FIG. 18 has a flat plate 911 formed of an electrical insulating material such as silicon and having a cavity 920, a circuit pattern 912 for an integrated circuit element disposed on a lower surface of the flat plate 911, a piezoelectric vibrator element 95 (an element) disposed inside the cavity 920, and electrode pads 914 and an insulating coat 916 disposed on the lower surface of the flat plate 911.

Further, the oscillator 9 has through interconnections 927 which are disposed inside through holes penetrating the flat plate 911, and are coupled to the circuit pattern 912, and mount electrodes 926 which are disposed on a bottom surface of the cavity 920, and are coupled to the through interconnections 927. Due to the through interconnections 927, it is possible to achieve the electrical coupling between the circuit pattern 912 and the mount electrodes 926.

Further, the oscillator 9 has an electrically-conductive adhesive 98 which is disposed inside the cavity 920, and bonds the mount electrodes 926 and the piezoelectric vibrator element 95 to each other. Due to the electrically-conductive adhesive 98, the electrical coupling between the piezoelectric vibrator element 95 and the mount electrodes 926 is also achieved.

Further, the oscillator 9 has a lid 930 disposed on an opening part of the cavity 920. The lid 930 is bonded to an outer circumference of an edge part of the opening part of the cavity 920 via an adhesive 932. Thus, the inside of the cavity 920 is airtightly sealed in an inert gas atmosphere or a reduced-pressure atmosphere.

In such an oscillator 9, it is possible to apply the wiring substrate 1 described above to the structure including the flat plate 911, and the electrodes, the interconnections, and so on provided to the flat plate 911.

Therefore, the oscillator 9 according to the present embodiment is provided with the wiring substrate 1 described above and the element. Further, the wiring substrate 1 and the elements are electrically coupled to each other, and the wiring substrate 1 and the elements are stacked on one another. Since the failure such as the broken line due to the missing of the through interconnections 927 penetrating the flat plate 911 is difficult to occur, such an oscillator 9 becomes high in reliability. Further, due to such reliability, reduction in size and an increase in density of the oscillator 9 become possible. Therefore, it is possible to realize the oscillator 9 small in size and high in reliability.

It should be noted that as the oscillator 9, there can be cited, for example, a quartz crystal oscillator (SPXO), a voltage-controlled crystal oscillator (VCXO), a temperature-compensated crystal oscillator (TCXO), a voltage-controlled SAW oscillator (VCSO), an oven-controlled crystal oscillator (OCXO), an SAW oscillator (SPSO), an MEMS oscillator, and an atomic oscillator.

### 5. Electronic Apparatus and Vehicle

The wiring substrate 1 described above can also be applied to a wiring substrate provided to a variety of types of electronic apparatus other than the electronic apparatuses described above. As such electronic apparatuses, there can be cited, for example, a personal computer, a mobile phone, a digital still camera, a smartphone, a tablet terminal, a wearable terminal such as a timepiece including a smart watch, a pair of smart glasses, a head-mounted display (HMD), a laptop personal computer, a television set, a video camera, a video cassette recorder, a car navigation system, a pager, a personal digital assistance including a communication function, an electronic dictionary, an electronic calculator, a computerized game machine, a word processor, a workstation, a video phone, a security video monitor, a pair of electronic binoculars, a POS terminal, medical equipment such as an electronic thermometer, an electronic manometer, an electronic blood sugar meter, an electrocardiogram measurement instrument, an ultrasonograph, and an electronic endoscope, a fish detector, a variety of types of measurement instruments, a variety of types of gauges such as gauges for a car, an aircraft, a ship or a boat, a base station for mobile terminals, and a flight simulator. By providing the wiring substrate 1, such an electronic apparatus as described above becomes one small in size and high in reliability based on the high electrical reliability and the easiness of reduction in size provided to the wiring substrate 1.

Further, the wiring substrate 1 described above can also be applied to variety of types of equipment provided to a variety of types of vehicles. As such equipment, there can be cited, for example, an electronic control unit (ECU) such as a keyless entry system, an immobilizer, a car navigation system, a car air-conditioner, an anti-lock braking system (ABS), an air-bag system, a tire pressure monitoring system (TPMS), an engine controller, a braking system, a battery monitor for a hybrid car or an electric car, or a vehicle attitude control system. By providing the wiring substrate 1, such a variety of types of equipment provided to the vehicle as described above become those small in size and high in reliability based on the high electrical reliability and the easiness of reduction in size provided to the wiring substrate 1.

Although the wiring substrate, the method of manufacturing the wiring substrate, the inkjet head, the MEMS device, and the oscillator according to the present disclosure are hereinabove described based on the illustrated embodiments, the present disclosure is not limited to these embodiments.

For example, the method of manufacturing the wiring substrate according to the present disclosure can also be one obtained by adding a step having an arbitrary purpose to the embodiments described above.

Further, the wiring substrate, the inkjet head, the MEMS device, and the oscillator according to the present disclosure can be those obtained by replacing a constituent of the embodiments with an arbitrary constituent having substantially the same function, or can also be those obtained by adding an arbitrary constituent to the embodiments.

What is claimed is:

1. A wiring substrate comprising:
a first substrate having a first surface and a second surface at an opposite side to the first surface;
a first interconnection disposed on the first surface;
a second interconnection disposed on the second surface; and
a through interconnection electrically coupling the first interconnection and the second interconnection to each other, and penetrating the first substrate, wherein
the through interconnection includes
a first through interconnection coupled to the first interconnection, and
a second through interconnection coupled to the second interconnection, and
the first through interconnection and the second through interconnection partially overlap each other in a plan view from a thickness direction of the first substrate.

2. The wiring substrate according to claim 1, wherein
a cross-sectional area in the first surface of the first through interconnection is larger than a cross-sectional area of the first through interconnection at a position shifted toward the second surface from the first surface.

3. The wiring substrate according to claim 1, wherein
a cross-sectional area in the second surface of the second through interconnection is larger than a cross-sectional area of the second through interconnection at a position shifted toward the first surface from the second surface.

4. The wiring substrate according to claim 1, wherein
at least one of a cross-sectional shape in the first surface of the first through interconnection and a cross-sectional shape of the second through interconnection in the second surface has a ring-like shape in the plan view from the thickness direction of the first substrate.

5. A method of manufacturing a wiring substrate, comprising:
preparing a first substrate having a first surface and a second surface at an opposite side to the first surface;
forming a first catalytic layer including noble metal on the first surface and forming a second catalytic layer including noble metal on the second surface;
making the first substrate provided with the first catalytic layer and the second catalytic layer have contact with an etchant to perform etching from the first surface toward the second surface to form a first hole and to perform etching from the second surface toward the first surface to form a second hole, and then connecting the first hole and the second hole to obtain a through hole; and
supplying an electrically-conductive material inside the through hole to obtain a through interconnection.

6. The method of manufacturing the wiring substrate according to claim 5, wherein
in the forming of the first catalytic layer and the second catalytic layer, the first catalytic layer and the second catalytic layer are formed so that the first catalytic layer and the second catalytic layer partially overlap each other in the plan view from the thickness direction of the first substrate.

7. An inkjet head comprising:
the wiring substrate according to claim 1; and
a piezoelectric element substrate having a second substrate, and a piezoelectric element which is disposed on the second substrate, and is electrically coupled to the second interconnection, wherein
the wiring substrate and the piezoelectric element substrate are stacked on one another.

8. An MEMS device comprising:
the wiring substrate according to claim 1; and
an element, wherein
the wiring substrate and the element are electrically coupled to each other, and
the wiring substrate and the element are stacked on one another.

9. An oscillator comprising:
the wiring substrate according to claim 1; and
a plurality of elements, wherein
the wiring substrate and the elements are electrically coupled to each other, and
the wiring substrate and the elements are stacked on one another.
